(19) United States
(12) Patent Application Publication
(10) Pub. No.: US 2009/0179275 A1
(43) Pub. Date: Jul. 16, 2009

(54) SEMICONDUCTOR MEMORY DEVICE JUNCTION AND METHOD OF FORMING THE SAME

(75) Inventor: Hyun Soo Shon, Kyeongki-do (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: Hynix Semiconductor Inc., Icheon-si (KR)

(21) Appl. No.: 12/131,584

(22) Filed: Jun. 2, 2008

(30) Foreign Application Priority Data
Jan. 10, 2008 (KR) 10-2008-0003152

(51) Int. Cl. H01L 27/088; H01L 21/8234

(52) U.S. Cl. 257/368; 438/307; 257/E21.616; 257/E27.06

(57) ABSTRACT

The present invention relates to semiconductor memory device junction and a method of forming the same. The semiconductor memory device junction may include a semiconductor substrate having gate lines formed thereon, and a junction having first and second junction elements formed by implanting impurities of a different mass into the semiconductor substrate between the gate lines. The method of forming a semiconductor memory device junction may include providing a semiconductor substrate having gate lines, forming an auxiliary layer along a surface of the semiconductor substrate including the gate lines, implanting impurities into the semiconductor substrate between gate lines to form a first junction element, and implanting impurities into the semiconductor substrate to form a second junction element, wherein the impurities implanted to form the first junction element and the second junction element have different masses.

### CROSS-REFERENCES TO RELATED APPLICATIONS

The priority benefit of Korean Patent Application No. 10-2008-0003152, filed on Jan. 10, 2008, the disclosure of which is incorporated by reference in its entirety, is claimed.

### BACKGROUND OF THE INVENTION

1. Field of Disclosure

The invention generally relates to a junction of a semiconductor memory device and a method of forming the same that can improve a program disturbance characteristic.

2. Brief Description of Related Technology

A semiconductor memory device includes a plurality of memory cells for storing data and a plurality of transistors for transferring driving voltages. A flash memory device, for example, includes a plurality of memory cells that are connected in series to form strings. Select transistors are formed at both ends of each string. The memory cells formed in different strings are electrically connected through word lines, and the select transistors are electrically connected through a select line.

FIG. 1 is a sectional view illustrating a conventional method of forming junctions of a semiconductor memory device. Referring to FIG. 1, a select line SL and a plurality of word lines WL0 and WL1 (only two are shown for convenience of description) are formed on a semiconductor substrate 10. Specifically, each of the select lines SL and the word lines WL0 and WL1 can have a stacked structure that includes a tunnel insulating layer 12, a first conductive layer 14 for a floating gate, a dielectric layer 16, a second conductive layer 18 for a control gate, and a gate mask pattern 20. Junctions 10a are formed between the select line SL and the word lines WL0 and WL1 and between the word lines WL0 and WL1. The junctions 10a are electrically connected to each other. In general, a junction 10a is formed by injecting an N type impurity, for example, phosphorous (P) into the semiconductor substrate.

In particular, at the time of a program operation of the flash memory device, a well of strings other than a selected string, including to-be-programmed cells, is boosted in order to prevent electrons from being injected into memory cells connected to selected word lines. However, as the distance between the select line SL and the word lines WL0 and WL1 is narrowed due to an increased level of integration of semiconductor memory devices, the introduction of hot carriers can be increased. That is, electrons may be introduced into memory cells that should not be programmed. This may widen or change the width of threshold voltage distribution and increase a program disturbance characteristic.

### SUMMARY OF THE INVENTION

Disclosed herein is a semiconductor memory device junction and method of forming the same that can reduce a program disturbance characteristic.

According to one embodiment, a semiconductor memory device junction may include: a semiconductor substrate having gate lines formed thereon, and a junction having first and second junction elements formed in the semiconductor substrate between the gate lines. The first junction element includes impurities having a different mass than impurities of the second junction element. For example, the impurities of the second junction element may have a greater mass than the impurities of the first junction element.

The first and second junction elements may have different widths. For example, the second junction element can have a width narrower than a width of the first junction element. The first junction element may be deeper than the second junction element.

The impurities of the first junction element can include, for example, phosphorus (P) and the impurities of the second junction element can include, for example, arsenic (As).

One embodiment of the disclosed method of forming a semiconductor memory device junction includes: providing a semiconductor substrate having gate lines formed thereon; forming an auxiliary layer along a surface of the semiconductor substrate including the gate lines; implanting impurities into the semiconductor substrate between the gate lines to form a first junction element; and implanting impurities into the semiconductor substrate between the gate lines to form a second junction element. The impurities implanted to form the second junction element may have a different mass than the impurities implanted to form the first junction element. For example, the impurities implanted to form the second junction element may have a greater mass than the impurities implanted to form the first junction. For example, phosphorous (P) can be implanted to form the first junction element, and arsenic (As) having a mass greater than that of phosphorous (P) can be implanted to form the second junction element.

The first junction element can be formed, for example, by applying an energy of approximately 15 to 30 KeV to the impurities. The second junction element can be formed, for example, by applying an energy of approximately 10 to 25 KeV to the impurities. The auxiliary layer can be formed, for example, of SiO₂.

In another embodiment, the step of forming the auxiliary layer can be performed prior to the step of implanting impurities to form the first junction element.

In yet another embodiment, the step of implanting impurities to form the first junction element can be performed prior to the step of forming the auxiliary layer.

In a further embodiment, the first and second junction elements can have different widths. For example, the second junction element can have a width narrower than the width of the first junction element.

In another embodiment, the first junction element can be deeper than the second junction element.

In yet another embodiment, the method may further include annealing the semiconductor substrate to activate the implanted impurities to diffuse within the semiconductor substrate.

### BRIEF DESCRIPTION OF THE DRAWINGS

For a more complete understanding of the disclosure, reference should be made to the following detailed description and accompanying drawings.

FIG. 1 is a sectional view illustrating a conventional method of forming a semiconductor memory device junction.

FIGS. 2A to 2C are sectional views illustrating a method of forming a semiconductor memory device junction in accordance with an embodiment of the present invention.

FIGS. 3A to 3D are sectional views illustrating a method of forming a semiconductor memory device junction in accordance with another embodiment of the present invention.

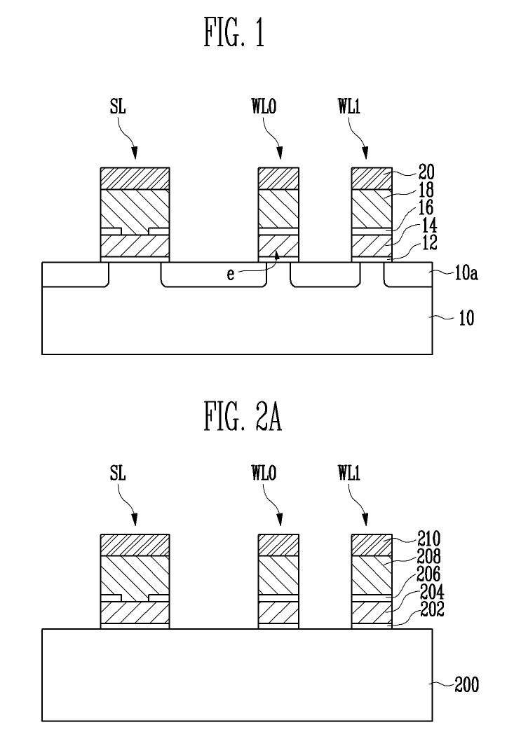

While the disclosed device and method are susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DETAILED DESCRIPTION OF SPECIFIC EMBODIMENTS

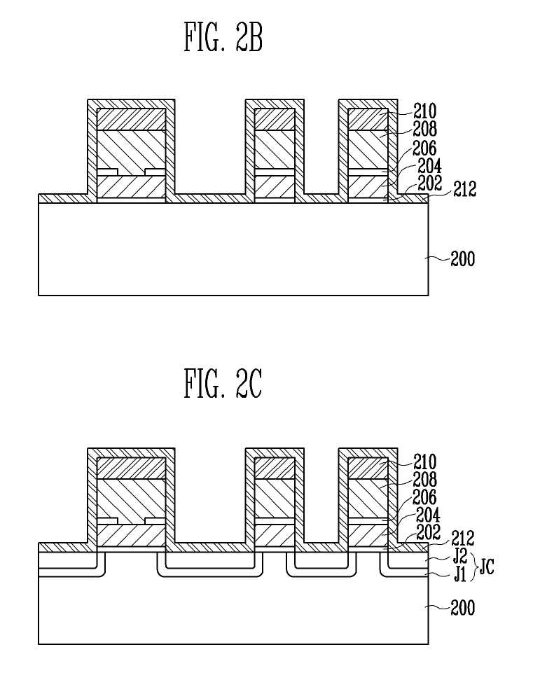

Referring to FIG. 2A, a flash memory device includes a plurality of memory cells for storing data and select transistors for transferring driving voltages. The memory cells can be electrically connected to each other through word lines WL0 and WL1, and the select transistors can be electrically connected to each other through a select line SL.

A tunnel insulating layer 202, a first conductive layer 204 for a floating gate, a dielectric layer 206, a second conductive layer 208 for a control gate, and a gate mask pattern 210 are formed over a semiconductor substrate 200. Word lines WL0 and WL1 and a select line SL are formed by patterning the second conductive layer 208, the dielectric layer 206, the first conductive layer 204, and the tunnel insulating layer 202 along the gate mask pattern 210. For example, one string can include 16 or 32 word lines and can include a source select line and a drain select line. Of them, the source select line SL, the 0^{th} word line WL0, and the first word line WL1 are shown in the drawing. Further, at the time of patterning, a part of the tunnel insulating layer 202 of a region that is patterned may remain in order to be used as a subsequent buffer layer.

Referring to FIG. 2B, an auxiliary layer 212 is formed along a surface of the select line SL, word lines (including the word lines WL0 and WL1), and the exposed semiconductor substrate 200. The auxiliary layer 212 can be used to generate a difference in the width between junction elements in a formation process of a subsequent junction. The auxiliary layer 212 is preferably formed of an oxide, but may also be formed, for example, of SiO₂. In this embodiment, the auxiliary layer 212 may be formed to a thickness of approximately 50 to 100 angstroms by performing, for example, Chemical Vapor Deposition (CVD) with good step coverage. Further, the auxiliary layer 212 may also be used as a buffer layer during an ion implantation process used to form subsequent junctions.

Referring to FIG. 2C, junctions JC are formed in the semiconductor substrate 200 by performing an ion implantation process. The junctions JC may be formed on the semiconductor substrate 200 having the auxiliary layer 212 formed thereon. Alternatively, the junctions JC may be formed before forming the auxiliary layer 212 on the semiconductor substrate 200. In a semiconductor substrate 200 in which a cell region and a peri region are defined, the ion implantation process is preferably performed using a mask pattern having an open cell region. For example, a photoresist pattern (not shown) having an open cell region can be formed on the semiconductor substrate 200 including the select lines SL and the word lines (including the word lines WL0 and WL1). A junction JC that includes a first junction element J1 and a second junction element J2, having, for example, different widths, can be formed by implanting impurities into the semiconductor substrate 200 using a first ion implantation process and a second ion implantation process performed along the photoresist pattern (not shown). Preferably, impurities having different masses are implanted during the first and second ion implantation processes and the first and second ion implantation processes are preferably performed using different energies to implant the impurities into the substrate.

The first ion implantation process may be performed, for example, using phosphorous (P) as an N type impurity and by applying, for example, an energy of approximately 15 to 30 KeV to the impurity. The second ion implantation process can then be performed using, for example arsenic (As) as an N type impurity and by applying, for example, an energy of approximately 10 to 25 KeV to the impurity, which is lower than that of the first ion implantation process. After the first and second ion implantation processes are carried out, the photoresist pattern (not shown) may be removed.

An annealing process that activates the implanted impurities can then be performed. If the annealing process is performed, the implanted impurities are diffused within the semiconductor substrate 200. The impurities, phosphorous (P) for example, of the first junction element J1, can diffuse more rapidly than the impurities, arsenic (As) for example, of second junction element J2. Specifically, phosphorous (P) has a mass of 31 g/mol, whereas arsenic (As) has a mass of 75 g/mol. If the annealing process is performed, the diffusion width of phosphorous (P) having a mass smaller than that of arsenic (As) can be widened. Accordingly, a width of the first junction element J1 becomes wider than a width of the second junction element J2 and a depth of the first junction element J1 becomes deeper than that of the second junction element J2. Further, the second junction element J2 is narrowed by the auxiliary layer 212 formed on sidewalls of the select line SL, the word lines WL0, and WL1. Thus, even after the annealing process is performed, the diffused width of the second junction element J2 is also narrow.

Thus, although hot carriers are generated in a subsequent program operation, the migration speed of the hot carriers within the second junction element J2 becomes slow, thus reducing a program disturbance phenomenon. For example, at the time of a program operation of a flash memory device, a selected word line can be applied with a program voltage (for example, 24.3 V) and the remaining word lines can be applied with a pass voltage (for example, 9.5 V). Further, a bit line of a selected string can be applied with a ground voltage (for example, 0 V) and the remaining bit lines can be applied with a power supply voltage (for example, Vcc). In this embodiment, a boosting phenomenon is generated in the semiconductor substrate 200 of unselected strings. In this case, the different widths and different masses of the impurities of the first and the second junction elements J1 and J2 can prohibit the migration of hot carriers. Consequently, a change in the threshold voltage of the flash memory device can be reduced and reliability of the device can be improved.

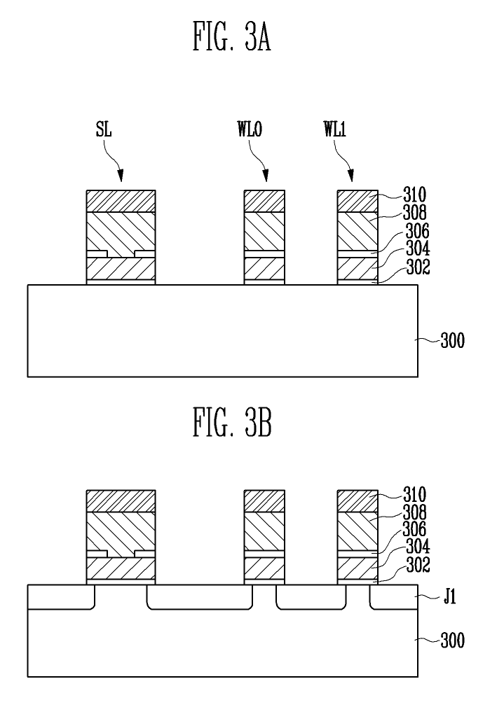

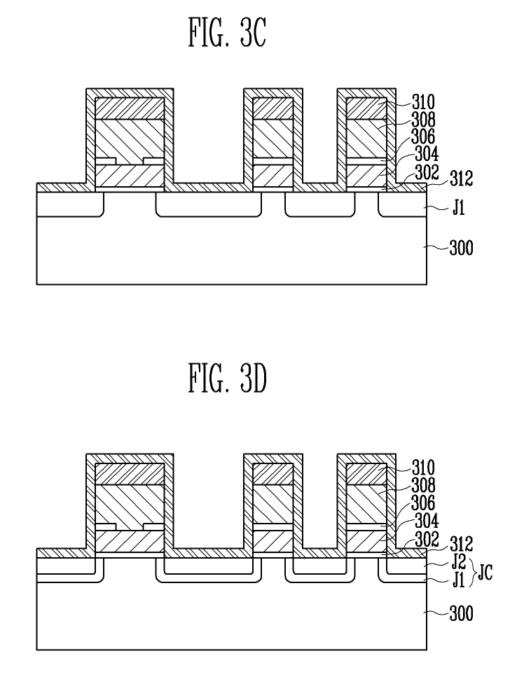

Referring to FIG. 3A, there is provided a semiconductor substrate 300 in which a select line SL and word lines WL0 and WL1 are formed on a cell region. Specifically, the select line SL and the word lines WL0 and WL1 can be formed to have a stacked structure that includes a tunnel insulating layer 302, a first conductive layer 304 for a floating gate, a dielectric layer 306, a second conductive layer 308 for a control gate, and a gate mask pattern 310. In this embodiment, a part of the dielectric layer 306 of the select line SL is removed in order to electrically connect the first conductive layer 304 and the second conductive layer 308.

Referring to FIG. 3B, a first junction element J1 is formed by implanting impurities into the semiconductor substrate 300, using a first ion implantation process. A photoresist pattern (not shown) where a peri region is covered, but a cell region is opened, can be formed. The first ion implantation process can then be performed. In the case where an N type impurity is used, the first ion implantation process can be performed using phosphorous (P), for example, as the impurity. Here, the first ion implantation process is preferably performed by applying an energy of approximately 15 to 30 KeV to the impurity. After the first junction element J1 is formed, the photoresist pattern (not shown) can be removed and an annealing process for activating the implanted impurity (for example, P) can be performed.

Referring to FIG. 3C, an auxiliary layer 312 can be formed along a surface of the select line SL, the word lines WL0 and WL1, and the semiconductor substrate 300 having the first junction elements J1 formed therein. The auxiliary layer 312 can be formed, for example, of an oxide and may also be formed, for example, of SiO₂.

The auxiliary layer 312 is formed on the sidewalls of gate lines (for example, SL, WL0 and WL1) formed on the semiconductor substrate 300 and, therefore, can be formed by performing, for example, CVD with a good step coverage characteristic. The auxiliary layer 212 may be formed to a thickness of approximately 50 to 100 angstroms.

Referring to FIG. 3D, a second junction element J2 is formed by implanting impurities into the semiconductor substrate 300, using a second ion implantation process on the auxiliary layer 312 and the semiconductor substrate 300 where the first junction elements J1 are formed. In this embodiment, after a photoresist pattern (not shown) where the cell region is opened is formed, the second ion implantation process is preferably performed by, preferably, implanting an impurity having a different mass than the mass of the impurity implanted in the first ion implantation process, and using an energy different from that of the first ion implantation process. For example, the second ion implantation process can be performed using arsenic (As) as the impurity and by applying, for example, an energy of approximately 10 to 25 KeV to the impurity.

Thereafter, the photoresist pattern (not shown) is removed and an annealing process for activating the impurity implanted into the second junction element J2 is performed. In this embodiment, the second junction element J2 has a narrower width than that of the first junction element J1 according to a thickness of the auxiliary layer 312. Further, the mass of arsenic (As) implanted to form the second junction element J2 is 75 g/mol, which is greater than 31 g/mol of phosphorous (P) implanted to form the first junction element J1. Thus, the second junction element J2 has a diffusion width smaller than that of the first junction element J1 although the annealing process is performed, so it is diffused at a width narrower than that of the first junction element J1. The junction JC has a double structure. Accordingly, although hot carriers are generated in the junction JC when the flash memory device is operated subsequently, migration of the hot carriers within the second junction element J2 can be prohibited. Even if the hot carriers are moved within the first junction element J1, the migration distance of the hot carriers is lengthened by the second junction element J2. Accordingly, unnecessary program operations can be prevented from operating. Consequently, reliability of the flash memory device can be improved.

As described above, the double junctions JC that include first and second junction elements J1 and J2 can be formed in the semiconductor substrate 200 between the select line and the word lines of the cell region using impurities having a different mass. Hence, the occurrence of the leakage current can be prohibited, the migration of hot carriers can be prohibited upon occurrence of the hot carriers and, therefore, a program disturbance characteristic can be reduced. Accordingly, reliability of semiconductor memory devices can be improved.

The specific embodiments of the present invention have been described for illustrative purposes Those skilled in the art will appreciate that various modifications, additions and substitutions are possible, without departing from the spirit and scope of the invention as recited in the following claims. Therefore, the scope of the present invention is not limited by or to the embodiments as described above, and should be construed to be defined only by the appended claims and their equivalents.

What is claimed is:

1. An article, comprising:
a semiconductor substrate having gate lines formed thereon; and,
a junction comprising first and second junction elements formed in the semiconductor substrate between the gate lines, wherein the first junction element comprises impurities having a different mass than impurities of the second junction element.

2. The article of claim 1, wherein the impurities of the second junction element have a greater mass than the impurities of the first junction element.

3. The article of claim 2, wherein the second junction element has a width narrower than that of the first junction element.

4. The article of claim 2, wherein the first junction element is deeper than the second junction element.

5. The article of claim 2, wherein the impurities of the first junction element comprise phosphorus (P).

6. The article of claim 2, wherein the impurities of the second junction element comprise arsenic (As).

7. The article of claim 1, wherein the first and second junction elements have different widths

8. A method of forming a semiconductor memory device junction, the method comprising:
providing a semiconductor substrate having gate lines formed thereon;
forming an auxiliary layer along a surface of the semiconductor substrate including the gate lines;
implanting impurities into the semiconductor substrate between the gate lines to form a first junction element; and,
implanting impurities into the semiconductor substrate between the gate lines to form a second junction element, wherein the impurities implanted to form the second junction element have a different mass than the impurities implanted to form the first junction element.

9. The method of claim 8, wherein the impurities that form the second junction element have a greater mass than the impurities that form the first junction element.

10. The method of claim 9, wherein the impurities that form the first junction element comprise phosphorous (P); and, the impurities that form the second junction element comprise arsenic (As).

11. The method of claim 10, wherein the step of implanting impurities to form the first junction element comprises applying an energy of approximately 15 to 30 KeV to the impurities.

12. The method of claim 10, wherein the step of implanting impurities to form the second junction element comprises applying an energy of approximately 10 to 25 KeV to the impurities.

13. The method of claim 8, wherein the auxiliary layer comprises SiO₂.

14. The method of claim 8, wherein the step of implanting impurities to form the first junction element is performed prior to the step of forming the auxiliary layer.

15. The method of claim 8, wherein the step of forming the auxiliary layer is performed prior to the steps of implanting impurities to form the first and second junction elements.

16. The method of claim 8, wherein the first junction element has a different width than the second junction element.

17. The method of claim 16, wherein the second junction element has a width narrower than a width of the first junction element.

18. The method of claim 8, wherein the first junction element is deeper than the second junction element.

19. The method of claim 8, further comprising annealing the semiconductor substrate including the junction to activate the implanted impurities to diffuse within the semiconductor substrate.

20. The method of claim 19, wherein the impurities that form the first junction element have a smaller mass than the impurities that form the second junction element; and wherein the impurities that form the first junction element have a greater diffusion width than the impurities that form the second junction element.
